(19) United States
(12) Patent Application Publication
(10) Pub. No.: US 2018/0079588 A1
(43) Pub. Date: Mar. 22, 2018

(54) SYSTEMS AND METHODS FOR IMPROVED ELECTRONIC DEVICE PACKAGING AND DELIVERY

(71) Applicant: T-Mobile USA, Inc., Bellevue, WA (US)

(72) Inventors: John D. Whittington, Sammamish, WA (US); Virgil R. Mabalay, Covington, WA (US); Andrew W. Smith, Seattle, WA (US); Matthew A. Smith, Georgetown, IN (US)

(73) Assignee: T-Mobile USA, Inc.

(21) Appl. No.: 15/268,743

(22) Filed: Sep. 19, 2016

(51) Int. Cl. B65D 85/30; B65D 77/22; B65D 61/00; B65B 61/20; H05K 5/02; H05K 5/00; H02J 7/35

(52) U.S. Cl. CPC B65D 85/30; B65D 77/22; B65D 61/00; B65B 61/20; H02J 7/35; H05K 5/0017; H05K 5/0247; H05K 5/0243; H05K 5/0208

(57) ABSTRACT

Systems and methods for providing modular, customizable packaging. The system can include a shipping container and one or more exterior panels. The exterior panels can be used to provide customized aesthetics and functionality to the shipping container. The combined system can provide a custom shipping container designed to meet the shipping requirements of various shipping providers without additional packaging. The shipping container and/or exterior panels can comprise additional components including displays, speakers, keyboards, and scent dispensers, among other things. This system can provide a customized and upgraded presentation for a variety of products including electronic devices. The system can utilize 3D scanning and printing, among other things, to provide custom exterior graphics and components. The system can also enable personalized, secure deliver of the product to the consumer.

### BACKGROUND

Computers, cellular phones, and other electronic devices are ubiquitous. The combination of the Internet, cellular technologies, and modern electronics, among other things, has created an explosion in the number and types of electronic devices available (e.g., cellular phones, smart phones, tablets, laptops, etc.). Users rely on smart phones, for example, for interne access, e-mail, navigation, and even status.

As such, device providers attempt to lure consumers and differentiate themselves from the market using a variety of methods. Users can be attracted to devices based on particular technical features, aesthetic design, and price, among other things. Thus, one customer may be looking for a device that provides the features they desire at the lowest price point, while other customers may be willing to pay more for a more stylish or prestigious device.

Of course, another selling point is to provide upgraded or “platinum” service to customers. Hotels offer concierge service, for example, that provides personalized service and exclusive access to guests for a premium. Similarly, platinum credit cards offer early access to tickets, points, or discounts, among other things. High net worth customers place a premium on their time, for example, and may be willing to pay more for accessories and services that save them time.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items or features.

FIG. 1 is a perspective view of a secure delivery container, in accordance with some examples of the present disclosure.

FIG. 2A is a perspective view of a shipping container, in accordance with some examples of the present disclosure.

FIG. 2B is a perspective view of the shipping container base with custom exterior panels, in accordance with some examples of the present disclosure.

FIG. 3A is a front, perspective view of the inside of the shipping container of FIG. 2A, in accordance with some examples of the present disclosure.

FIGS. 3B and 3C are side, cross-sectional views of the shipping container in the closed (FIG. 3B) and open (FIG. 3C) position, in accordance with some examples of the present disclosure.

FIG. 4 is a component level schematic for one or more of the electronic devices in the system, in accordance with some examples of the present disclosure.

FIG. 5 is a flowchart depicting a method for creating the custom exterior panels, in accordance with some examples of the present disclosure.

### DETAILED DESCRIPTION

Examples of the present disclosure relate generally to packaging and delivery systems for electronic equipment. The packaging can include, for example, a number of visual, tactile, and/or aural experiences to provide customers with an improved experience. In some examples, the packaging can provide additional customization, setup, and other features to provide an “in-store” experience to online or other remote customers. The packaging can also enable electronic equipment to be delivered to customers in a more convenient, efficient, and secure manner.

To simplify and clarify explanation, the disclosure is described herein as systems and methods for use with cellular phones. One skilled in the art will recognize, however, that the disclosure is not so limited. While the systems and methods are useful in conjunction with cellular phones and their packaging and delivery, it should be understood that the systems and methods can just as easily be used for other electronic devices, such as tablets, laptops, and GPSs; and, indeed with other electronic and non-electronic products. The system can be used anytime a shipping container with additional features is desired to provide the user with an enhanced experience and improved customer service.

The manufacturing methods, materials, and systems described hereinafter as making up the various elements of the present disclosure are intended to be illustrative and not restrictive. Many suitable materials, struts, systems, and configurations that would perform the same or a similar function as the systems described herein are intended to be embraced within the scope of the disclosure. Such other systems and methods not described herein can include, but are not limited to, vehicles, systems, networks, materials, and technologies that are developed after the time of the development of the disclosure.

Customers who order cell phones and other equipment online do not necessarily receive the same experience as those shopping in a retail store. This is particularly true for customers who purchase high-end equipment. In other words, high-end customers may receive upgraded service including, but not limited to, hands-on setup assistance, customized support, and/or additional accessories. Thus, while a high-end customer in the store receives “platinum” service, when ordering online, these customers simply receive a cardboard box delivered by UPS like all customers.

It may be desirable to create an experience for customers that is as good, or better, than an in-store experience. This can include additional technology and luxury included in the packaging, special aesthetic treatments, and sensory stimulation to provide a complete experience. This can also include more customized setup and support, special delivery, and authentication services.

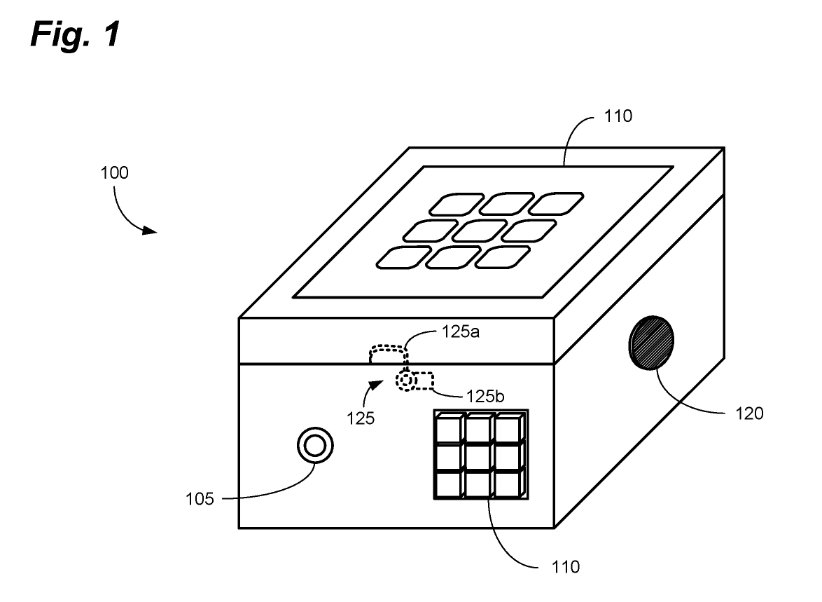

A problem with ordering equipment (e.g., cell phones, tablets, smart watches, etc.) online is that the product packaging is generally placed in a cardboard shipping box and delivered using conventional methods (e.g., UPS or USPS). Thus, at most, the user merely has to sign for an otherwise non-descript package. To this end, as shown in FIGS. 1-3, examples of the present disclosure can comprise packaging that includes a number of additional features.

Unsubsidized, high-end cell phones, for example, can cost $700-1500. Thus, theft and misdelivery can be a significant problem. In addition, delivery by personal courier can be faster, more personalized, and more service oriented. A courier can deliver the phone to any location, for example, including the users current location. It would be useful, however, for the courier to be able to verify the identity of the recipient to ensure proper delivery. Indeed, as discussed below, the system can enable the courier to positively identify the user using biometric information, for example, or information previously provided by the user (e.g., a password, passcode, etc.).

As shown in FIG. 1, therefore, to facilitate authentication of the user's identity, in some examples, the container 100 can include one or more authentication components. In some examples, the container 100 can include a scanner 105. In some examples, the scanner can include a fingerprint scanner. In this manner, when delivered, the user's identity can be verified by simply placing their finger over the scanner 105. The fingerprint information can be obtained from the user's current cell phone, for example, or provided by the user online.

In other examples, the scanner 105 can include a retinal scanner. As such, the user can simply place their eye in front of the scanner to verify their identity. Again, the data required for this verification can be retrieved from the user's current cell phone, for example, provided online, or at a customer service location.

In other examples, the container 100 can include a keypad 110 instead of, or in addition to, the scanner 105. The keypad 110 can comprise, for example, a standard numeric or alpha-numeric keypad to enable the user to enter a password, code, or other authentication. In other examples, the keypad 110 can include pictograms, or other symbols, that the user has previously chosen for authentication. So, for example, the keypad can include a pencil, a car, dice, a CD, and other pictures or pictograms. The user can then authenticate their identity by selected the correct pictures in the correct order.

In still other examples, the packaging can include a screen 115. As discussed below, in some examples, the screen 115 can be used to provide the current location or address for the user to enable the courier to locate the user. In other examples, the screen 115 can include a touchscreen. In this configuration, the screen 115 can enable the user to provide touchscreen inputs to enter a password, code, gesture, or other authentication method.

In some examples, the screen 115 can provide feedback during the authentication process. So, for example, if the user enters the wrong information, the screen 115 may turn red and warn the user that they have a limited number of attempts left. Conversely, when the user enters the correct authentication information, the screen may turn green, display a welcome message, or provide other relevant information.

In some examples, the screen 115 can also display a personalized greeting to the user. In other words, to provide the aforementioned platinum service, for example, after authentication, the screen 115 can display a welcome message including the user's name, the type of phone purchased, specialized websites (e.g., “members only” websites), setup instructions, phone numbers, or other information relevant to the user. So, for example, the screen 115 may provide personalized setup information relevant to the user, the phone, or the carrier, for example, to make setting the phone up easier and more personalized.

The container 100 can also include one or more audio devices 120. In some examples, the audio devices 120 can include one or more speakers, or other devices, to provide audio output such as, for example, personalized messages, music, authentication sounds, or other feedback. So, for example, if the user enters incorrect authentication information, the audio devices 120 can play a siren or other warning noise. Similarly, if the user enters correct authentication information, the audio devices 120 can play a triumphant sound. In some examples, upon authentication, the audio devices 120 can play the user's favorite song, or other personalized greeting. The audio devices 120 can play, for example, a personalized welcome message including the user's name, phone model, or other personalized information.

In some examples, the container 100 can also include a locking device 125. In some examples, as shown, the locking device 125 can include a mechanical latch 125a and a solenoid 125b. In other examples, the locking device 125 can include, for example, a magnetic lock, linear actuator, or solenoid. Thus, regardless of the authentication method sued, the locking device 125 can remain in the locked position until one of the inputs 105, 110, 115 receives appropriate authentication information. When the correct authentication information is received, the solenoid 125b can rotate the mechanical latch 125a to open the container 100.

Due to the cost of high-end cell phones and the potential for loss to the provider, cell phones are often shipper “signature required.” Thus, one possible inconvenience for the user when ordering a phone online is the need to be in a particular location to sign for the package when delivered. This can be inconvenient when the delivery window is outside certain parameters. If a user is normally at work during the day, for example, but the phone is to be delivered to the user's home during the day, then the user may be forced to take time off from work or work from home. In addition, unless the courier has an example of the user's signature, merely obtaining a signature at the delivery location merely proves that someone at the delivery location signed for the package. Thus, a roommate may sign for the phone, for example, rather than the user.

Providing the authentication and information discussed above on the container 100 enables a courier (or other deliver means) to provide a higher level of authentication and enables the courier to be used independent of the user's location because the container 100 can provide at least two levels of authentication. The first level is that the user must provide pre-supplied authentication information to open the container 100. This information may be provided to the user from the provider, or vice-versa; and, provided the user has not shared this information, this authenticates the user to the courier at a higher level than a signature.

In addition, as mentioned above, the screen 115, for example, can provide current location information for the user. Thus, by delivering the container 100 to the user's dynamic location, rather than a static location such as an address, an additional level of authentication is provided. In other words, the courier has delivered the container 100 to the correct user because they are in the correct location.

This can also enable the courier to provide a higher level of service. In other words, because the courier is able to locate the user for delivery, the user is free to continue with their day unencumbered. Thus, while the provider may supply a delivery window and ask that the user stay “local” or within a certain radius during that window, the user's location is somewhat irrelevant. The courier could intercept a user out for a walk, for example, simply by tracking their location as they arrive in the area.

As mentioned above, to improve user experience for users that order phones online, for example, it would be beneficial to ship the phone in something other than a cardboard box. In addition to courier delivery, for example, a shipping container that looked like the phone on the outside, for example, or included other luxury features would provide a higher level of service and excitement. A user receiving a phone in such packaging would also be provided with a similar experience to an in-store user, where the user may feel a sense of prestige, for example, amongst friends and/or other customers.

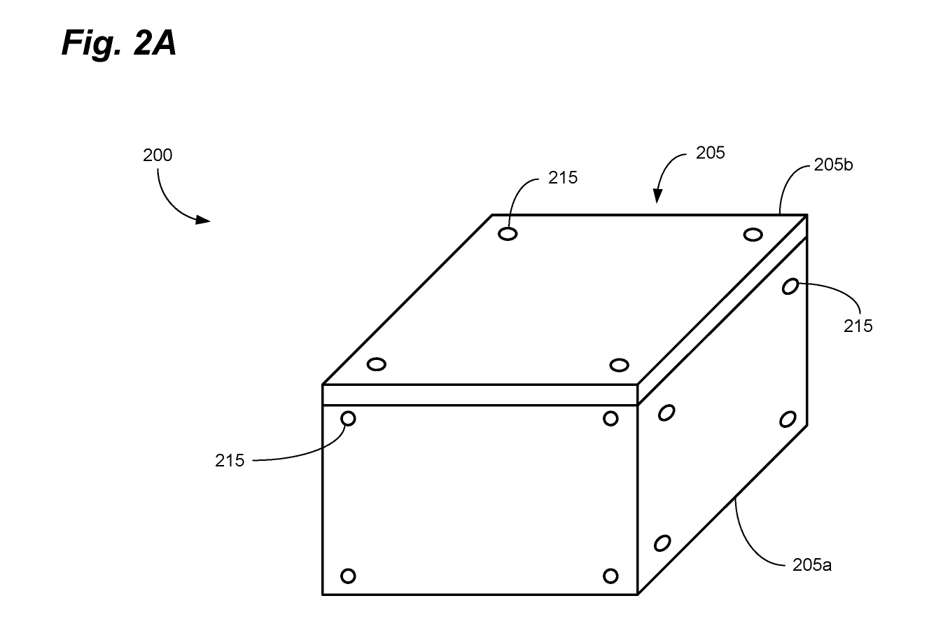

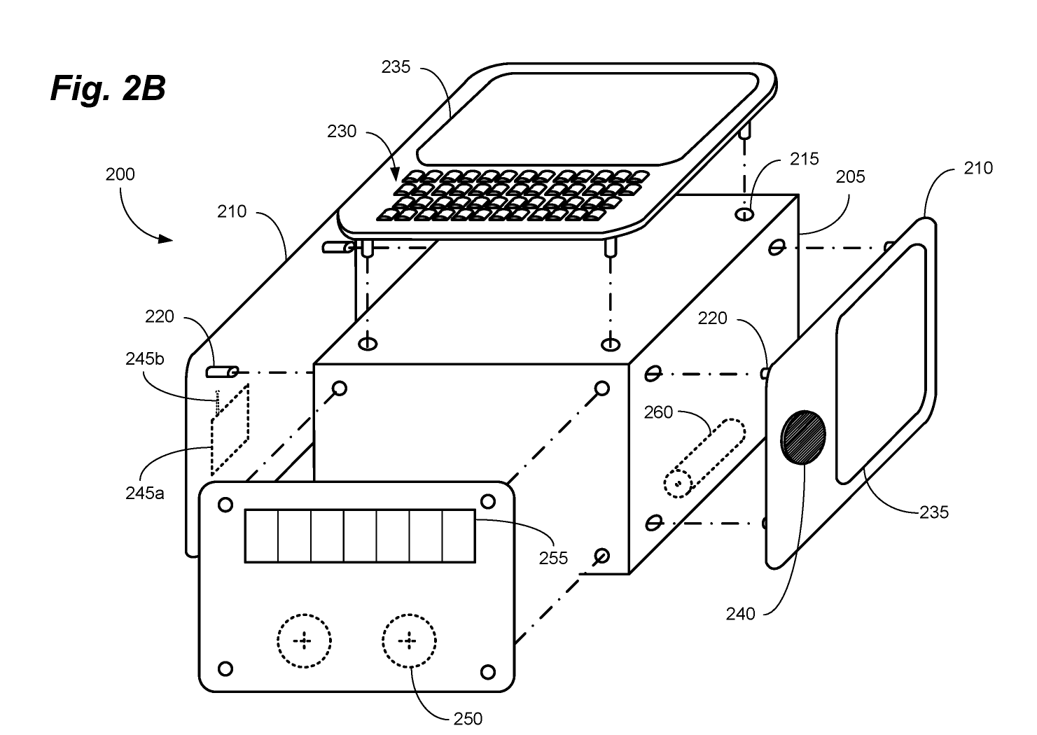

To this end, as shown in FIGS. 2A and 2B, a system 200 for packaging electronic devices can comprise a shipping container 205 (FIG. 2A) for the shipment of an electronic device, for example, and one or more exterior panels 210. The shipping container 205 can comprise packaging suitable to ship the product to the customer. The shipping container 205 can be approved by UPS, the USPS, and other carriers for size and strength to preclude the use of additional packaging (e.g., cardboard boxes or other packaging materials). The shipping container 205 can comprise, for example, plastic, aluminum, steel, cardboard, or paperboard. The shipping container 205 can comprise a base 205a and a lid 205b. The lid 205b can be pivotally coupled to the base 205a to provide access when open and to prevent access when closed. As discussed below, in some examples, the lid 205b can be lockable and/or can require authentication from the user.

The shipping container 205 can also comprise one or more receptacles 215. The receptacles 215 can permanently or detachably couple the exterior panels 210 to the shipping container 205. In some examples, the receptacles 215 can comprise holes in the shipping container suitable to accept complementary fasteners 220 on the exterior panels 210. In some examples, adhesive, such as epoxy or glue, can be placed in the holes to affix the exterior panels 210 to the shipping container 205. The receptacles 215 can also comprise, for example, threaded holes, snaps, magnets, or adhesive tape.

As shown in FIG. 2B, in some examples, the exterior panels 210 can comprise one or more fasteners 220 to detachably or permanently couple the exterior panels 210 to the shipping container 205. In some examples, as mentioned above, the fasteners 220 can comprise pins and the shipping container 205 can comprise complementary holes to receive the pins. In other examples, the receptacles 215 can comprise threaded holes, for example, and the fasteners 220 can comprise complementary bolts or screws. In still other embodiments, the exterior panels 210 can be affixed to the shipping container 205 using, for example, adhesive, epoxy, glue, or adhesive tape (e.g., 3M Scotch-Mount molding tape).

The exterior panels 210 can comprise a myriad of different components to improve the aesthetics and/or function of the shipping container 205, including various electronic functions. In some examples, at least one of the exterior panels 210a can be designed to look and/or be shaped like the phone inside the shipping container 205. In some examples, all of the exterior panels 210 can be designed to look like a side of the phone, for example, such that the shipping container 205 essentially becomes a 3D depiction of the phone (albeit significantly larger).

The exterior panels 210 can comprise keyboards 230, displays 235, and other components that can be functional or merely decorative. In this manner, the user is provided with a similar experience as the in-store user, who may receive the phone in the original packaging (i.e., rather than a cardboard box), thus adding to the experience. Indeed, for expensive or exclusive phones, this can enable the user to enjoy the prestige and/or exclusivity of the phone upon arrival.

In some examples, some or all of the exterior panels 210 can be functional. The exterior panels 210 can comprise modular keyboards 230, displays 235, speakers 240, and other components. In some examples, the keyboard 230 and/or display 235, for example, can be used for the aforementioned authentication process and to display images and text, as desired. In some examples, the display 235 and/or speakers 240 can provide a welcome message customized to the user and/or the phone.

In some examples, one or more of the exterior panels 210 can comprise a locating device, such as a GPS receiver 245a and antenna 245b. As discussed above, the GPS receiver 245a can be used to provide the delivery location, including the user's current location even if the user is moving. In this manner, a courier, or other delivery means, can locate the user at the time of delivery rather than the user waiting at home.

In some examples, one or more of the exterior panels 210 can comprise one or more external batteries 250 to power the various components 230-245. The external batteries 250 can comprise a lithium-ion, nickel-cadmium (Ni-Cad), or alkaline battery. As shown, in some examples, the external batteries 250 can comprise button-style batteries to enable the exterior panels 210 to be relatively thin. In some examples, one or more of the exterior panels 210 can also comprise a solar panel 255. The solar panel 255 can power the components 230-245 directly or can charge the external batteries 250 to power the components 230-245 among other things.

In some examples, the shipping container 205 can comprise one or more internal batteries 260. In this configuration, one or more of the receptacles 215 can be in electrical communication with the one or more internal batteries 260 to provide power to the exterior panels 210 and to connect the exterior panels 210 to each other. The fasteners 220 on the exterior panels 210, in turn, can comprise electrical contacts electrically coupleable to the receptacles 215. In this manner, the solar panel 255 can charge the internal battery 260, for example, and the internal battery 260 can provide power to the components 230-245.

Each exterior panel 210 can comprise at least one fastener 220 to connect to the positive side of the internal batteries 260. In some examples, each exterior panel 210 can also comprise at least one fastener 220 to connect to the negative side of the internal batteries 260. Of course, this could also be achieved by grounding the shipping container 205 (i.e., connecting it to the negative battery terminal) and then grounding the exterior panels 210 directly to the shipping container 205. In some examples, the receptacles 215 and fasteners 220 can comprise complementary metal conductors (e.g., brass, copper, or aluminum) to electrically couple the components 230-245 and/or exterior panels 210 to the internal batteries 260 or each other.

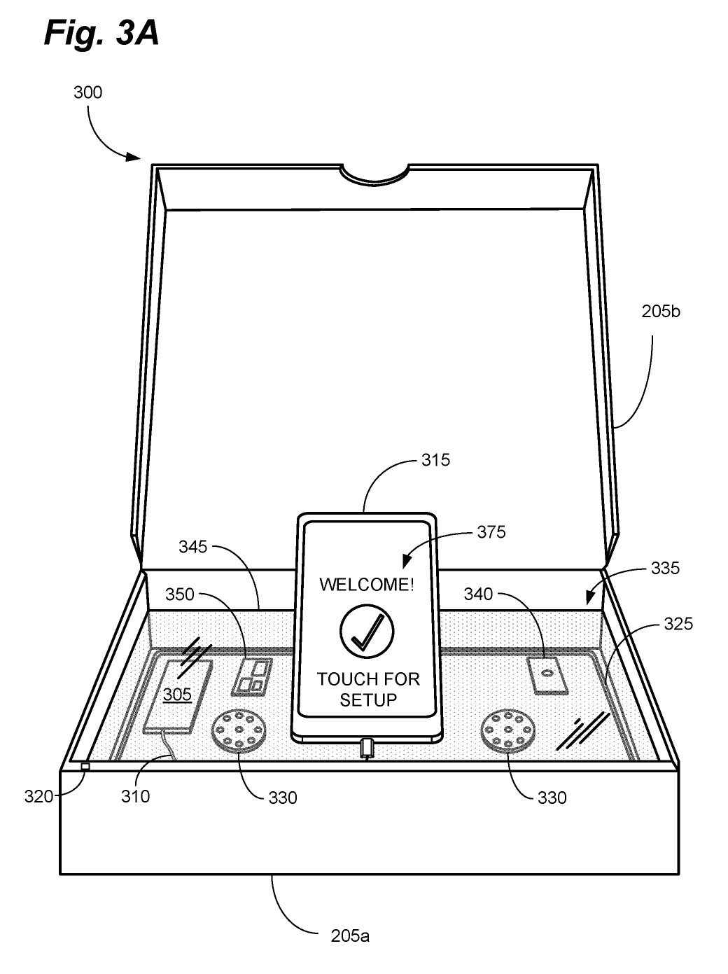

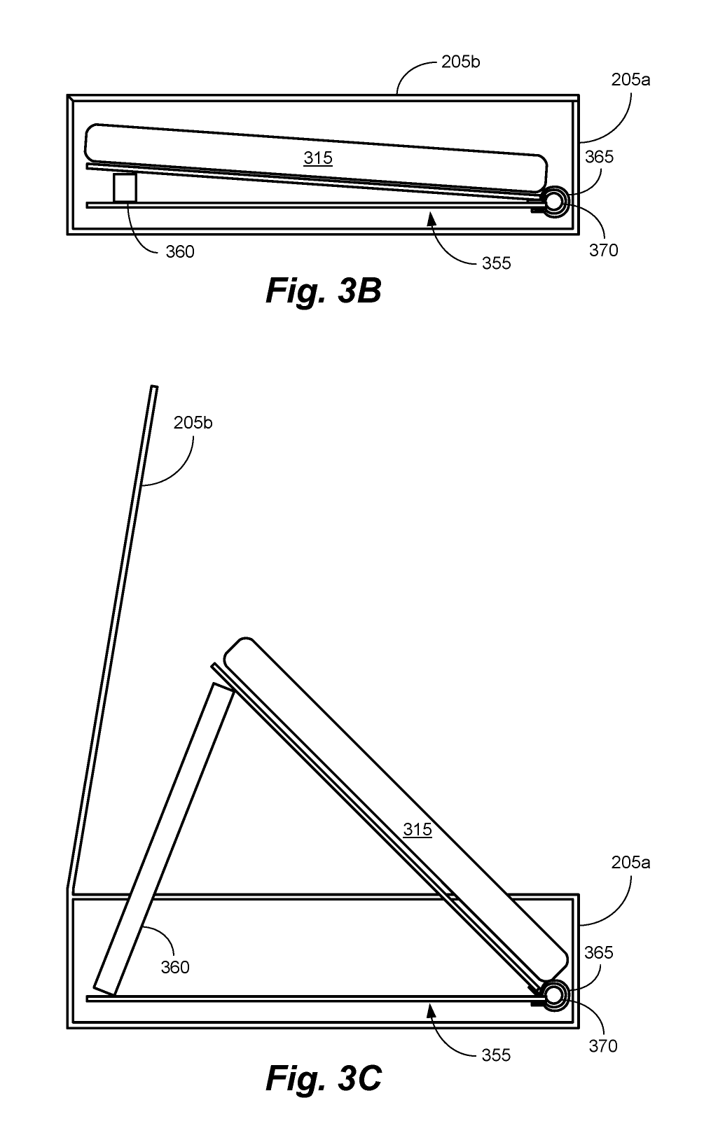

As shown in FIG. 3A, examples of the present disclosure can also comprise a system 300 including the shipping container 205 and a number of additional components on the inside of the shipping container 205 to improve the user's experience. In some examples, the system 300 can comprise an onboard power source 305 and/or a power cord 310. The onboard power source 305 can comprise, for example, a battery or capacitor to provide power to the phone 315. In some examples, the battery in the phone 315 can be used instead of, or in addition to, the onboard power source 305.

In some examples, the system 300 can also comprise a switch 320. The switch 320 can indicate when the shipping container 205 is open and can, for example, connect the onboard power source 305 to the phone 315. In other words, to prevent the onboard power source 305 from being depleted in storage or in transit, it can be disconnected. When the user opens the lid 205b of the shipping container 205, however, the onboard power source 305 can be connected to the phone 315 to ensure that the phone 315 has sufficient power to power up regardless of the state of charge of the internal battery in the phone 315.

In some examples, the system 300 can also include a light source 325 and one or more speakers 330. In some examples, these components 325, 330 can also be triggered by the switch 320 such that when the user opens the shipping container 205, the interior portion 335 of the shipping container 205 is illuminated and music, a welcome message, or other sounds are provided. The light source 325 can comprise a number of powered light sources such as, for example, one or more LEDs, neon lights, fluorescent lights, or incandescent bulbs to provide illumination for the shipping container 205. The light source 325 can also comprise a number of non-powered light sources such as, for example, chemiluminescent or bioluminescent compounds.

As mentioned above, one downside to purchasing a phone online is that the user does not get the full “in-store” experience. For many, part of this experience is the “smell” of new electronics, much like “new car smell.” To this end, in some examples, the system 300 can also comprise one or more scent dispensers 340. The scent dispenser 340 can comprise various smells or combinations of smells design to emulate the smell of the retail store. The scent dispenser 340 may contain a small amount of ozone, for example, to provide an electronics smell. Other scents, such as new carpet, leather, cleaning products, etc., can be combined to provide an “in-store” smell within the shipping container 205.

In some examples, the system 300 can also comprise one or more dividers 345. The divider 345 can comprise, for example, an opaque or semi-opaque material configured to obscure the components on the interior portion 335 of the shipping container 205. In some examples, the divider 345 can be positioned such that the onboard power source 305, power cord 310, speakers 330, scent dispenser 340, and other components of the system 300 are disposed below the divider 345, while the phone 315 is disposed above the divider 345. In this manner, the “inner workings” of the system 300 can be hidden from view, while the phone 315 is on display.

In some examples, the divider 345 can also include, or act as, a light diffuser. In other words, the divider can be semi-opaque and/or can include a pattern, or other means, to diffuse the light from the light source 325 in the desired manner. In some examples, the divider 345 can be used to focus light on the phone 315, for example. In other examples, the divider 345 can be used to diffuse the light from one or more single point light sources 325 into a diffuse and even glow in the interior portion 335 of the shipping container 205.

In some examples, the system 300 can also comprise a transceiver/controller 350. As the name implies, the transceiver/controller 350 can comprise a microprocessor and a transceiver. The microprocessor can be used to control the light source 325 and other components in the shipping container. In some examples, the transceiver can be used for remote programming, location services, connection to internet support or setup sites, and other communications purposes. In some examples, the transceiver can be used to receive user information, for example, or to receive information related to welcome messages or setup menus, among other things.

As shown in FIGS. 3B and 3C, in some examples, the system 300 can also comprise a cradle 355 for the phone 315. As shown, the cradle 355 can have a retracted position (FIG. 3B) and an extended position (FIG. 3C). As shown, in the retraced position, the phone 315 can be substantially inside the shipping container 205. In the extended position, on the other hand, the phone 315 can be displayed at an angle such that at least a portion of the phone 315 is outside the interior portion 335 of the shipping container 205. can be disposed In this manner, the phone 315 can be easily placed in the shipping container for shipping, but can then be presented to the user upon opening the shipping container 205. The cradle 355 can include, for example, a blow-molded carrier, clips, or cable ties, to secure the phone 315 to the cradle 355 during shipping.

In some examples, the cradle 355 can also comprise one or more extending devices 360, 365. The extending devices 360, 365 are shown symbolically. One of skill in the art will recognize that the extending devices 360, 365 can comprise a number of different components. The first extending device 360 can comprise a linear device such as, for example, a linear actuator, pneumatic or hydraulic cylinder, or linear spring. The second extending device 365 can comprise a rotary device located near the pivot 370 of the cradle 355. The second extending device 365 can comprise, for example, a rotary spring, a linear spring (e.g., mounted longitudinally on the pivot 370), a servo motor, or rotary actuator. In some examples, one or more of the extending devices 360, 365 can be triggered by the switch 320 to move from the retracted position to the extended position to present the phone 315 to the user.

Referring back to FIG. 3A, in some examples, the screen 375 on the phone 315 can be used to present the user with a welcome message and/or setup instructions. In some examples, because the components in the system 300 were pre-programmed, the phone 315 can be partially or fully setup automatically and/or customized based on the user's settings and preferences in the current phone. In some examples, the phone 315 can be programmed to provide prompts on the screen 375 to guide the user though the setup process. In still other embodiments, the screen 375 can also guide the user to exclusive websites, or other features, related to the upgraded, or platinum, service.

Of course, while described above as separate components in the shipping container 205, one or more of the components in the system 300 could be shared with the phone 315. In other words, instead of providing separate speakers 330, the system 300 could merely utilize the speakers on the phone 315. Similarly, rather than providing a separate transceiver/controller 350, the processor and transceiver on the phone 315 could be used. Indeed, addition components, such as the phone's modems, vibration motor, and flash could be used to enhance the user's experience. When the user opens the shipping container 205, for example, the system 300 can activate the flash on the phone 315 to blink rapidly and the vibration motor to vibrate to increase excitement. In addition, the vibration motor could be used to provide haptic feedback during the setup process, for example.

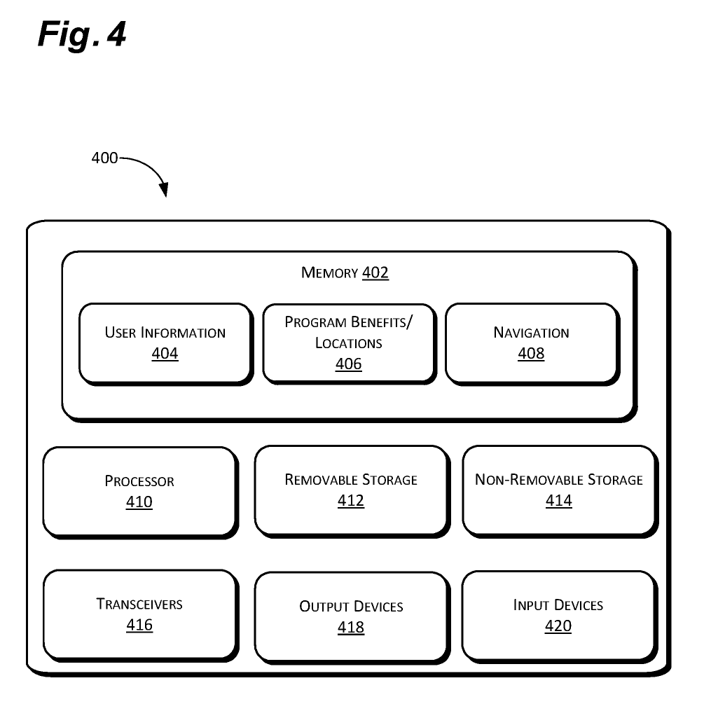

As shown in FIG. 4, the shipping container 205 and/or exterior panels 210 can comprise a number of components to enable each component 205, 210 to perform the above-mentioned functions. As discussed below, each component 205, 210 can comprise memory 402 configured to include at least user information 404, program benefits and location information 406, and navigation software 408. Also, each component 205, 210 can include one or more processor(s) 410, removable storage 412, non-removable storage 414, transceivers 416, output device(s) 418, and input device(s) 420. The components 205, 210 may additionally contain a policy engine to receive, create, transmit, and manage the various messages and commands.

In various implementations, the memory 402 can be volatile (such as RAM), non-volatile (such as ROM, flash memory, etc.), or some combination of the two. The memory 402 can also comprise user information 404. User information 404 can include the users account number, address, billing information, and other relevant information. User information 404 can also include the phone 315 the user has purchased, the billing package, and schedule delivery date and time, among other things. The system 300 can use this information to program the phone 315, for example, and to determine a delivery location, among other things.

In some examples, the memory 402 can also include program benefits and location information 406. This can include the user's inclusion in a platinum level service package, for example, and website addresses or applications related to the user's benefits. This can be used to direct the user to appropriate website to set up their phone 315 or utilize certain exclusive benefits (e.g., concierge-type setup and services). The program benefits and location information 406 can also include information related to the user's rate plan, benefits with corporate partners of the provider, and other information.

In some examples, the memory 402 can also comprise navigation software 408. As discussed above, the system 200, 300 can use the navigation software 408 to enable a courier, for example, to locate the user's house, or to locate the user in real-time. In some examples, the user may be receiving a new phone 315 from the same provider they use with their old phone. In this manner, the navigation software 408 can use GPS or cellular locations services, for example, to locate the user in real-time. This can enable the phone 315 to be delivered to the user regardless of their location (within reason).

Each component 205, 210 may also include additional data storage devices (removable and/or non-removable) such as, for example, magnetic disks, optical disks, or tape. Such additional storage is illustrated in FIG. 4 by removable storage 412 and non-removable storage 414. The removable storage 412 and non-removable storage 414 can store the various programs and algorithms to enable the phone 315 to be fully or partially configured and to enable the system 200, 300 to present welcome screens, setup menus, and other functions to the user via the system 200, 300 and/or the phone 315.

Non-transitory computer-readable media may include volatile and nonvolatile, removable and non-removable tangible, physical media implemented in technology for storage of information, such as computer readable instructions, data structures, program modules, or other data. The memory 402, removable storage 412, and non-removable storage 414 are all examples of non-transitory computer-readable media. Non-transitory computer-readable media include, but are not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other tangible, physical medium which can be used to store the desired information and which can be accessed by the component 205, 210. Any such non-transitory computer-readable media may be part of the component 205, 210 or may be a separate database or databank.

In some implementations, the transceivers 416 include any sort of transceivers known in the art. For example, the transceivers 416 may include wired communication components, such as a wired modem or Ethernet port, for communicating with the other component 205, 210 or the provider's cellular or Internet-based network. Also or instead, the transceivers 416 may include wireless modem(s) to facilitate wireless connectivity with the other components 205, 210, the Internet, and/or an intranet. Further, the transceivers 416 may include a radio transceiver that performs the function of transmitting and receiving radio frequency communications via an antenna (e.g., WiFi or Bluetooth®).

In some implementations, the output devices 418 include any sort of output devices known in the art, such as a display (e.g., a liquid crystal or thin-film transistor (TFT) display), a touchscreen display, speakers, a vibrating mechanism, or a tactile feedback mechanism. In some examples, the output devices can play various sounds based on, for example, whether a component 205, 210 in the system is being opened for the first time, has been configured, and/or is connected to various other services. Output devices 418 also include ports for one or more peripheral devices, such as headphones, peripheral speakers, or a peripheral display.

In various implementations, input devices 420 include any sort of input devices known in the art. For example, input devices 420 may include a camera, a microphone, a keyboard/keypad, or a touch-sensitive display. A keyboard/keypad may be a standard push button alphanumeric, multi-key keyboard (such as a conventional QWERTY keyboard), a touchscreen, or one or more other types of keys or buttons, and may also include a joystick, wheel, and/or designated navigation buttons, or the like.

Examples of the present disclosure can also comprise a method 500 for creating unique shipping containers 205. The method 500 can enable each individual, or type of, shipping container 205 to be customized for a particular type of phone, a particular level of customer (e.g., gold vs platinum), or for advertising or marketing purposes. The method 500 can include various additive or subtractive manufacturing processes such as 3D printing or CNC machining.

At 505, to create one or more recreations or representations of portions of the phone 315, for example, the method 500 can start by 3D scanning the phone 315. All, or part, of the phone 315 can be scanned using a high-resolution 3D scanner. In some examples, 3D models of various phones 315, or parts of phones 315, can be created manually by a draftsman using a CAD or graphics program. This may be more cost effective if a relatively small selection of phones 315 are to be packaged using the system 200, 300 (e.g., if it is an exclusive service).

As mentioned above, it can be desirable to create special packaging to provide a higher level of service to customers who purchase, for example, special equipment, packages, or services. If a customer purchases a particularly expensive and feature-rich smart phone, for example, its arrival in a cardboard box may be somewhat anticlimactic. To then end, examples of the present disclosure can also comprise a method 500 for creating custom shipping containers.

In some examples, at 505, the method 500 can begin by obtaining a 3D image of the phone 315. In some examples, this can involve obtaining CAD files, or other relevant information, from the phone's manufacturer. In other examples, this can involve scanning the phone 315 with a 3D scanner 550 to obtain a 3D image 555 of the phone 315. 3D scanners 550 are relatively inexpensive and accurate. Thus, in some cases, such as when a large number of phones 315 are part of the method 500, a 3D scanner can be an efficient way to obtain a 3D image 555 of each type or model of phone. In addition, because the 3D image 555 is being used for substantially decorative purposes (though some technical features may be included), its absolute accuracy is less important.

At 510, to create one or more of the exterior panels 210 for the shipping container 205, the 3D image 555 can be sectioned into six partial 3D images, or “panels.” In some examples, the method 500 can simply remove a “box” from the middle of the 3D image 555, essentially leaving the six faces of the phone 315 behind. In other examples, the 3D image 555 can be sectioned into partial 3D images such that, for example, only the face 555a (e.g., the front surface) is used as an exterior panel 210 and the remaining portions of the 3D image 555 are discarded (e.g., the rear and sides of the phone 315 may be relatively featureless). Of course, any portion or all of the 3D image 555 could be used to form the exterior panels 210.

At 515, at least the shell of the exterior panel(s) 210 can be manufactured. In some examples, the exterior panels 210 may be purely aesthetic appliques for the outside of the shipping container 205. The exterior panels 210 may be designed to basically look like a large version of the phone 315. In addition, one or more of the exterior panels 210 can also be used to display logos (e.g., the provider's logo), advertising, instructions, website addresses, or other information. In some examples, one or more of the exterior panels 210 may be used as part of a co-branded advertising campaign and can include movie characters (e.g., superheroes) or other campaign materials. So, for example, the exterior panel 210 on the top of the shipping container 205 can comprise an accurate or characterized depiction of the phone 315, while one or more of the side exterior panels 210 can comprise a 3D superhero, movie title, or other materials.

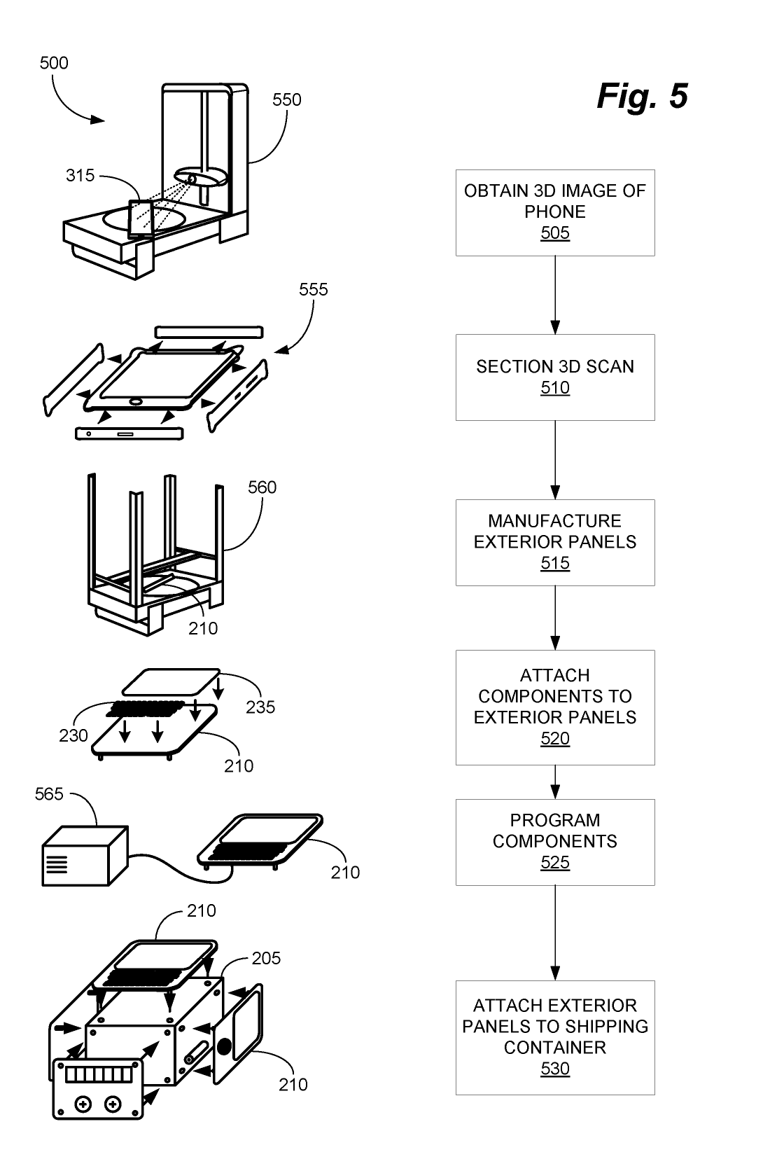

In some examples, as shown in FIG. 5, the exterior panels 210 can be created on a 3D printer 560. In this manner, exterior panels 210 of many shapes, sizes, and designs can be created. Indeed, each phone 315 could be shipped with unique exterior panels customized to the phone, the customer, and other variables. One or more of the exterior panels 210 can be, for example, physical representations of the partial 3D images. An exterior panel 210 can comprise the front surface of the phone 315, for example, scaled (e.g., stretched or shrunk) to fit the shipping container 205. In other examples, the exterior panels 210 can be, for example, blow molded, injection molded, CNC machined, or rotation molded.

At 520, additional components or materials can be added to the exterior panels 210. As mentioned above, in some examples, the exterior panels 210 can be purely decorative. In this configuration, the additional components can comprise additional appliques, overlays, decals, paint, coverings, or other decorations. In some examples, the exterior panels 210 can be painted or dipped in a “soft-touch” coating, for example, to provide a more luxurious feel. In other examples, the exterior panels 210 can be painted or dyed to match the phone 315.

In other examples, however, the additional components can be attached to the exterior panels 210 to provide additional functional properties. In some examples, as shown, the exterior panels 210 can include a display 235, a keyboard 230, or other electronic components. In this configuration, the manufactured exterior panel 210 can comprise an external shell that included pockets, fastening points, grooves, or other means to enable the components (e.g., the display 235 and keyboard 230) to be attached and wired. In some examples, the wiring can include electronically coupling the components, installing and connecting any power sources, and/or connecting the components to the fasteners 220, or other exterior power sources.

At 525, any additional electronic components that have been installed on the exterior panels 210 can be programmed with an external computing device 565 (e.g., a computer, server, laptop, flash reader, programmer, etc.). As mentioned above, this can included providing a customized welcome message for the customer, for example, or providing setup, or other, instructions, among other things. In some examples, the components can be programmed to display information related to the customer's benefits with the provider, websites that include special features or setup guidance, for example, or advertising and marketing materials to be displayed on the display 235. In some examples, the components can be programmed with the aforementioned password to enable the customer to verify their identity at delivery. In other examples, as discussed above, the components can include information related to the customer's “old” phone to enable the display 235 to provide the customer's location using GPS or cellular location services, among other things.

At 530, once programmed, the exterior panels 210 can be attached to the shipping container 205. As discussed above, in some examples, the exterior panels 210 can include electrical connections to components inside the shipping container 205 (e.g., the internal battery 260). In other examples, the exterior panels 210 can be purely aesthetic and can simply attach to the shipping container 205 to provide a customized look and feel. The exterior panels 210 can be attached to the shipping container 205 using any suitably robust method including, but not limited to, adhesives, screws, bolts, clips, pins, or welding (e.g., radio frequency (RF) welding).

The shipping container 205 and exterior panels 210 can provide a customized package that can be sued to safely ship a new phone 315 to a customer. The system 200, 300 can provide an exterior and interior with upgraded looks and/or features to provide a higher level of service to customers. In some examples, the system 200, 300 can be shipped as-is, with no external packaging, boxes, or other materials. The system 200, 300 can be designed to meet applicable shipping regulations for at least one carrier (e.g., USPS, UPS, or FedEx packaging requirements) without the use of additional packaging. The system 200, 300 can be custom tailored to each type of phone, each individual phone, each customer, or current advertising or marketing campaigns, among other things. The system 200, 300 can also provide an upgraded level of service to the customer including, for example, facilitating personalized, secure delivery, pre-programming, and assisted setup.

While several possible examples are disclosed above, examples of the present disclosure are not so limited. For instance, while a systems and methods for use with cellular phones has been disclosed, other electronic or non-electronic devices could be custom-packaged in a similar manner without departing from the spirit of the disclosure. In addition, the location and configuration used for various features of examples of the present disclosure such as, for example, the order of steps, the components of the system 200, 300, and the materials used can be varied according to a particular device or delivery methods that requires a slight variation due to, for example, the size or construction of the device, the fragility of the device, and/or the predicted handling of the system 200, 300 during delivery (e.g., mechanized sorting may be more apt to damage the system 200, 300 than courier delivery). Such changes are intended to be embraced within the scope of this disclosure.

The specific configurations, choice of materials, and the size and shape of various elements can be varied according to particular design specifications or constraints requiring a device, system, or method constructed according to the principles of this disclosure. Such changes are intended to be embraced within the scope of this disclosure. The presently disclosed examples, therefore, are considered in all respects to be illustrative and not restrictive. The scope of the disclosure is indicated by the appended claims, rather than the foregoing description, and all changes that come within the meaning and range of equivalents thereof are intended to be embraced therein.

What is claimed is:

1. A system comprising:
a shipping container to house an electronic device for shipment;
one or more exterior panels coupled to one or more exterior surfaces of the shipping container to provide at least one of aesthetic, mechanical, or electronic functions to the shipping container;
an authentication component to receive at least one input from a user to verify a user's identity; and
a locking device to control access to the shipping container based on one or more inputs from the authentication component;
wherein the shipping container with the exterior panel meets applicable shipping regulations for at least one carrier without additional packaging.

2. The system of claim 1, wherein the shipping container further comprises a cradle detachably coupled to the electronic device, the cradle comprises a retracted position and an extended position;
wherein, in the retracted position, the electronic device is positioned within an interior portion of the shipping container; and
wherein, in the extended position, at least a portion of the electronic device is positioned outside the interior portion of the shipping container.

3. The system of claim 1, further comprising:
one or more light sources, disposed in an interior portion of the shipping container, to provide illumination; and
a diffuser, disposed in the interior portion of the shipping container, to diffuse light from the one or more light sources;
wherein the diffuser is disposed between the one or more light sources and the electronic device.

4. The system of claim 1, further comprising:
a scent dispenser, disposed in an interior portion of the shipping container, to dispense a scent when the shipping container is opened.

5. The system of claim 1, further comprising:
an onboard power source disposed in an interior portion of the shipping container; and
a power cord to electrically connect the onboard power source to the electronic device.

6. The system of claim 5, further comprising:
a switch disposed proximate a lid of the shipping container;
wherein the switch connects the onboard power source to the electronic device when the lid is open; and
wherein the switch disconnects the onboard power source to the electronic device when the lid is closed.

7. A system comprising:
a shipping container to house an electronic device for shipment; and
one or more exterior panels coupled to one or more exterior surfaces of the shipping container to provide at least one of aesthetic, mechanical, or electronic functions to the shipping container;
wherein at least one of the one or more exterior panels comprises a physical representation of at least a portion of the electronic device; and
wherein the shipping container with the exterior panel meets applicable shipping regulations for at least one carrier without additional packaging.

8. The system of claim 7, wherein a first exterior panel of the one or more exterior panels comprises a touchscreen display to display images and text and to receive touchscreen inputs for the system.

9. The system of claim 7, wherein a first exterior panel of the one or more exterior panels comprises a keyboard to receive inputs for the system.

10. The system of claim 7, wherein a first exterior panel of the one or more exterior panels comprises:
one or more external batteries to power one or more electronic devices on the one or more exterior panels; and
a solar panel to charge the one or more external batteries.

11. The system of claim 7, wherein a first exterior panel of the one or more exterior panels comprising a first fastener to:
detachably couple the first exterior panel to the shipping container; and
electrically connect the first exterior panel to the shipping container.

12. The system of claim 11, wherein the shipping container further comprises:
one or more internal batteries; and
wherein the first fastener electrically connects one or more electronic components disposed on the first exterior panel to the one or more internal batteries.

13. The system of claim 7, wherein a first exterior panel of the one or more exterior panels comprises a speaker to provide an audio output for the system.

14. A method comprising:
obtaining a 3D image of an electronic device;
subdividing the 3D image into two or more partial 3D images;
manufacturing an exterior panel based on a first partial 3D image of the two or more partial 3D images; and
attaching the exterior panel to a shipping container, the shipping container to house an electronic device for shipment;
wherein the shipping container with the exterior panel meets applicable shipping regulations for at least one carrier without additional packaging.

15. The method of claim 14, further comprising:
attaching a first component to the exterior panel to provide at least one of aesthetic, mechanical, or electronic functions.

16. The method of claim 15, wherein the first component comprises an electronic device, the method further comprising:
programming the first component with an external computing device to provide at least one of an input or an output.

17. The method of claim 15, where the first component comprises a GPS receiver; and
wherein programming the first component with an external computing device comprises programming the GPS receiver with navigation software and location information related to a recipient of the electronic device in the shipping container.

18. The method of claim 15, wherein the first component comprises a display to provide an output, and further comprising:
attaching a keyboard to the exterior panel to provide an input.

19. The method of claim 14, wherein the first partial 3D image comprises an image of a front surface of the electronic device; and
wherein the exterior panel comprises a physical representation based on the first partial 3D image.

20. The method of claim 14, wherein manufacturing the exterior panel based on a first partial 3D image comprises 3D printing a physical representation of the partial 3D image.
